(19) United States
(12) Patent Application Publication
(10) Pub. No.: US 2011/0007058 A1
(43) Pub. Date: Jan. 13, 2011

(54) DIFFERENTIAL CLASS AB AMPLIFIER CIRCUIT, DRIVER CIRCUIT AND DISPLAY DEVICE

(75) Inventor: Haruhiko HISANO, Kanagawa (JP)

Correspondence Address: FOLEY AND LARDNER LLP;SUITE 500, 3000 K STREET NW, WASHINGTON, DC, 20007, US

(73) Assignee: NEC Electronics Corporation

(21) Appl. No.: 12/826,154

(22) Filed: Jun. 29, 2010

(30) Foreign Application Priority Data
Jul. 9, 2009 (JP) 2009-162827

(51) Int. Cl. G06F 3/038; H03F 3/45

(52) U.S. Cl. 345/211; 330/253; 330/257

(57) ABSTRACT

A driver circuit of the present invention comprises a differential class AB amplifier circuit which comprises: a first differential amplifier circuit configured to amplify differential input signals and output a first signal in a first voltage range; a second differential amplifier circuit configured to amplify the differential input signals and output a second signal in a second voltage range; and a class AB output circuit configured to input the first and the second signals as differential signals and amplify the differential signals, wherein the class AB output circuit comprises: a phase compensating capacitance section; and a current buffer circuit configured to control a current flowing thorough the phase compensating capacitance section.

### INCORPORATION BY REFERENCE

This application claims the benefit of priority based on Japanese Patent Application No. 2009-162827, filed on Jul. 9, 2009, the disclosure of which is incorporated herein by reference.

### BACKGROUND OF THE INVENTION

1. Field of the Invention

The present invention relates to a differential class AB amplifier circuit, and a driver circuit and a display device which are provided with the differential class AB amplifier circuit.

2. Description of Related Art

To simultaneously drive a large number of capacitive loads, a display device includes a plurality of differential class AB amplifier circuits as driver circuits. Each of those driver circuits voltage-drives, for example, a data line in each column of an LCD (Liquid Crystal Display) panel and outputs an analog signal corresponding to display data. Thus, it is required to enable so-called Rail-To-Rail input/output in a whole range of a power source voltage, and a voltage follower connected differential class AB amplifier has been used for this purpose. Furthermore, a low power consumption is required to those driver circuits.

Meanwhile, a liquid crystal panel has increased in size and in result parasitic capacitances on the data lines have also increased. Generally, in a case where a voltage follower connected two-stage differential amplifier circuit is used with an input circuit having a differential amplifier and an output circuit for amplifying a signal from the differential amplifier, its operation easily becomes unstable when load capacitances applied to the output increase. In some cases, the circuit may oscillate. For this reason, the voltage follower connected two-stage differential amplifier circuit is always provided with a phase compensating circuit to stabilize operation. However, the phase compensating circuit generally occupies a large area, and gives a great impact on an increase in chip area of the whole display device driver circuit having a large number of differential class AB amplifier circuits, thereby an increase in manufacturing costs is led. Therefore, the differential class AB amplifier circuit to be used requires, in particular, an area-saving and more efficient phase compensating circuit.

For example, Japanese Patent Publication No. JP-2005-124120A discloses a class AB amplifier circuit as the driver circuit with phase compensation. FIG. 1 is a circuit diagram illustrating the amplifier circuit. The amplifier circuit includes an N receiving differential amplifier 11, a P receiving differential amplifier 12 and a class AB output circuit 13.

The N receiving differential amplifier 11 includes N-channel MOS transistors 112, 113, an N-channel MOS transistor 111 and P-channel MOS transistors 114, 115. The N-channel MOS transistors 112, 113 form an N receiving differential pair inputting differential input signals Vin (+) and Vin (−). The N-channel MOS transistor 111 supplies a constant current controlled by a bias voltage BN1 to the N receiving differential pair. The P-channel MOS transistors 114, 115 form a current mirror circuit as an active load for the N receiving differential pair.

The P receiving differential amplifier 12 includes P-channel MOS transistors 122, 123, a P-channel MOS transistor 121 and N-channel MOS transistors 124, 125. The P-channel MOS transistors 122, 123 form a P receiving differential pair inputting the differential input signals Vin (+) and Vin (−). The P-channel MOS transistor 121 supplies a constant current controlled by a bias voltage BP1 to the P receiving differential pair. The N-channel MOS transistors 124, 125 form a current mirror circuit as an active load for the P receiving differential pair.

The class AB output circuit 13 includes a P-channel MOS transistor 131, an N-channel MOS transistor 132, a P-channel MOS transistor 133, an N-channel MOS transistor 134, a P-channel MOS transistor 135, an N-channel MOS transistor 136 and phase compensating capacitances 145, 146. The P-channel MOS transistor 131 receives an output of the N receiving differential amplifier 11 at its gate and is connected between a power voltage source VDD and an output node Vout. The N-channel MOS transistor 132 receives an output of the P receiving differential amplifier 12 at its gate and is connected between a power voltage source VSS and the output node. The P-channel MOS transistor 133 is controlled by a bias voltage BP2 and feeds a bias to the P-channel MOS transistor 131. The N-channel MOS transistor 134 is controlled by a bias voltage BN2 and feeds a bias to the N-channel MOS transistor 132. The P-channel MOS transistor 135 and the N-channel MOS transistor 136 are connected between gates of the transistors 131, 132 and receive bias voltages BP3, BN3, respectively, at respective gates to function as level shifters. The phase compensating capacitance 145 is connected between an input node (the gate of the transistor 131) to which a signal outputted from the N receiving differential amplifier 11 is applied and the output node Vout. The phase compensating capacitance 146 is connected between an input node (the gate of the transistor 132) to which a signal outputted from the P receiving differential amplifier 12 is applied and the output node Vout.

In the differential class AB amplifier circuit, even in an input voltage range in which one of the N receiving differential amplifier 11 and the P receiving differential amplifier 12 does not operate, the other of the N receiving differential amplifier 11 and the P receiving differential amplifier 12 operates, so that a signal can be transmitted to the class AB output circuit 13 in a whole input voltage range between the voltages provided by the power voltage sources VDD and VSS, that is, a Rail-To-Rail input is enabled.

As shown in FIG. 1, the class AB differential amplifier circuit includes phase compensating mirror capacitances 145, 146. The phase compensating mirror capacitance 145 is connected between the gate of the P-channel MOS transistor 131 in an output stage and the output node Vout. The phase compensating mirror capacitance 146 is connected between the gate of the N-channel MOS transistor 132 in an output stage and the output node Vout. With such a configuration, in a high-frequency operation, there are a current path through the mirror capacitances 145, 146 and a driving current path through the output stage transistors 131, 132, thereby necessarily causing a phase delay zero point. The phase delay zero point deteriorates a phase margin.

A plurality of commonly-known circuits are proposed as the phase compensating circuit having a zero-point compensating effect. For example, in a general simple two-stage differential amplifier, there are known a method of using a zero-point compensating resistance and a method of cutting a frequency-dependent current feed forward path as a cause of the phase delay zero point by a current buffer transistor.

The method of using the zero-point compensating resistance will be described referring to a two-stage amplifier circuit shown in FIG. 2, in which an output of a differential amplifier 200 is amplified by an amplifier circuit having a constant current source 204 and a transistor 202. The output of the differential amplifier 200 is applied to a gate of the transistor 202. An amplified signal is outputted from a connection node Vout between the constant current source 204 connected to the power voltage source VDD and a drain of the transistor 202. A phase compensating capacitance 206 is connected between the gate and drain of the transistor 202. In this case, a zero-point compensating resistance 201 is connected between the output node Vout and the gate of the transistor 202 in series with the phase compensating capacitance 206. The zero-point compensating resistance 201 is generally a resistance of a few hundreds of kΩ and occupies a large area.

The method of cutting the current feed forward path will be described referring to a two-stage amplifier circuit shown in FIG. 3, in which the output of the differential amplifier 200 is amplified by an amplifier circuit including a constant current source 304 and a transistor 302. The output of the differential amplifier 200 is applied to a gate of the transistor 302. An amplified signal is outputted from a connection node Vout between the constant current source 304 connected to the power voltage source VDD and a drain of the transistor 302. A phase compensating capacitance 306 is connected between the gate and drain of the transistor 302 via a current buffer transistor 301. A constant current source 303, the current buffer transistor 301 and a constant current source 305 are serially connected between the power voltage source VDD, VSS in this order. Consequently, the phase compensating capacitance 306 is connected between a connection node of the constant current source 303 and the transistor 301, and the output node Vout, and a connection node of the transistor 301 and the constant current source 305 is connected to the gate of the transistor 302.

As shown in FIG. 3, in the phase compensating circuit in which the frequency-dependent current feed forward path is cut by the current buffer transistor 301, the area of the phase compensating circuit increases because of the constant current sources 303, 305 added to the phase compensating circuit in addition to the current buffer transistor 301. Furthermore, the number of current paths between the power voltage sources VDD and VSS increases, resulting in an increase in power consumption.

### CITATION LIST

Patent Literature 1: JP2005-124120A

### SUMMARY OF THE INVENTION

The present invention provides a driver circuit, a method of driving a circuit and a display device which can improve the phase margin.

A driver circuit of the present invention comprises a differential class AB amplifier circuit which comprises: a first differential amplifier circuit configured to amplify differential input signals and output a first signal in a first voltage range; a second differential amplifier circuit configured to amplify the differential input signals and output a second signal in a second voltage range; and a class AB output circuit configured to input the first and the second signals as differential signals and amplify the differential signals, wherein the class AB output circuit comprises: a phase compensating capacitance section; and a current buffer circuit configured to control a current flowing through the phase compensating capacitance section.

A display device of the present invention comprises: a display panel; and a differential class AB amplifier circuit configured to drive the display panel, wherein the differential class AB amplifier circuit comprises: a first differential amplifier circuit configured to amplify differential input signals and output a first signal in a first voltage range; a second differential amplifier circuit configured to amplify the differential input signals and output a second signal in a second voltage range; and a class AB output circuit configured to input the first and the second signals as differential signals and amplify the differential signals, wherein the class AB output circuit comprises: a phase compensating capacitance section; and a current buffer circuit configured to control a current flowing through the phase compensating capacitance section.

A method of driving a circuit of the present invention comprises: amplifying differential input signals to generate a first signal in a first voltage range; amplifying the differential input signals to generate a second signal in a second voltage range; amplifying the first and the second signals as differential signals to generate an output signal; compensating phase delay in the output signal with a phase compensating capacitance; and controlling a current flowing through the phase compensating capacitance to control the compensating.

According to the present invention, the differential class AB amplifier circuit, the driver circuit and the display device which can improve a phase margin can be provided.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a diagram illustrating a configuration of a related class AB amplifier circuit;

FIG. 2 is a diagram for describing an amplifier circuit having a zero-point compensating resistance;

FIG. 3 is a diagram for describing an amplifier circuit having a current feed forward path cutting circuit;

FIG. 4 is a block diagram illustrating a configuration of a display device according to an embodiment of the present invention;

FIG. 5 is a diagram illustrating a configuration of a differential class AB amplifier circuit according to the embodiment of the present invention;

FIG. 6 is a diagram illustrating a configuration of a common bias circuit according to the embodiment of the present invention;

FIG. 7 is a diagram illustrating a configuration of the common bias circuit provided with switches addressing a test mode operation according to the embodiment of the present invention;

FIG. 8 is a diagram for describing setting of the switches according to the embodiment of the present invention; and

FIG. 9 is a diagram illustrating another configuration of the common bias circuit according to the embodiment of the present invention.

### DESCRIPTION OF PREFERRED EMBODIMENTS

Hereinafter, a driver circuit, a method of driving a circuit and display device according to an embodiment of the present invention will be described by referring to the accompanying drawings.

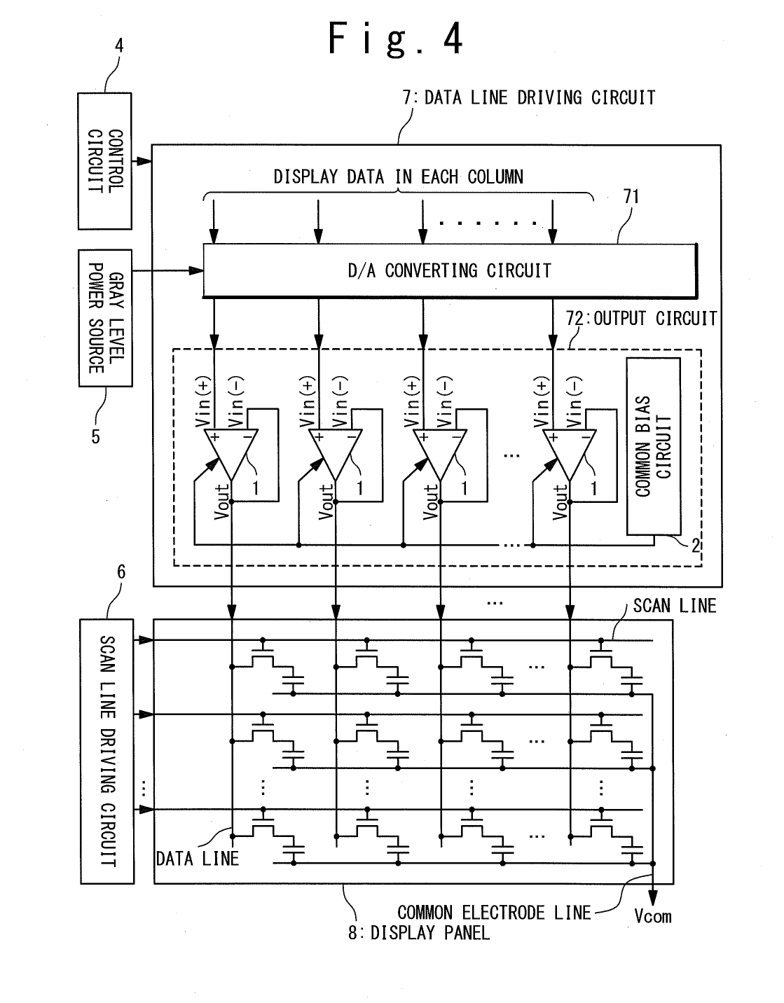

FIG. 4 is a block diagram illustrating a configuration of a display device according to the embodiment of the present invention. The display device includes a driver circuit having a control circuit 4, a gray level power source 5, a scan line driver circuit 6 and a data line driver circuit 7, and a display panel 8. The driver circuit of the display device drives the display panel 8.

An example of the display panel 8 is an active matrix drive-type color liquid crystal panel using thin film MOS transistors (TFT) as switching elements. Pixels are disposed in a matrix at intersection points of scan lines and data lines which are arranged at predetermined intervals in a row direction and a column direction. Each of the pixels includes a liquid crystal capacitance as an equivalently capacitive load and TFT, the gate of which is connected to the scan line. The liquid crystal capacitance and the TFT are serially connected between the data line and a common electrode line.

A scan pulse generated by the scan line driver circuit 7 based on a horizontal synchronizing signal and a vertical synchronizing signal is applied to the scan line in each row of the display panel 8. An analog data signal generated by the data line driver circuit 7 based on digital display data is applied to the data line in each column of the display panel 8 in a state where a common voltage Vcom is applied to the common electrode line. As a result, a character, an image and the like are displayed on the display panel 8.

The driver circuit of the display device parallelly voltage-drives the capacitive loads such as the data lines in each column in the display panel 8 and parallely outputs the analog signals of the column corresponding to display data. Thus, a plurality of differential class AB amplifiers which enable input/output in the whole power source voltage range between power source lines, that is, so-called Rail-To-Rail input/output are voltage follower connected and used.

The data line driver circuit 7 includes a D/A (Digital to Analog) converting circuit 71 and an output circuit 72. The D/A converting circuit 71 D/A converts the display data in each column by choosing a gray level voltage and outputs the converted data as an analog signal. The output circuit 72 outputs an impedance-converted analog display data signal and drives the data line in each column.

The output circuit 72 includes the plurality of differential class AB amplifier circuits 1 which are voltage follower connected to enable Rail-To-Rail input/output and a common bias circuit 2 for commonly supplying a bias voltage to the differential class AB amplifier circuits 1. Such an arrangement of the plural differential class AB amplifier circuits 1 can suppress an increase in circuit scale and drive the plurality of data lines in parallel. Furthermore, the arrangement can save circuit area and lower power consumption.

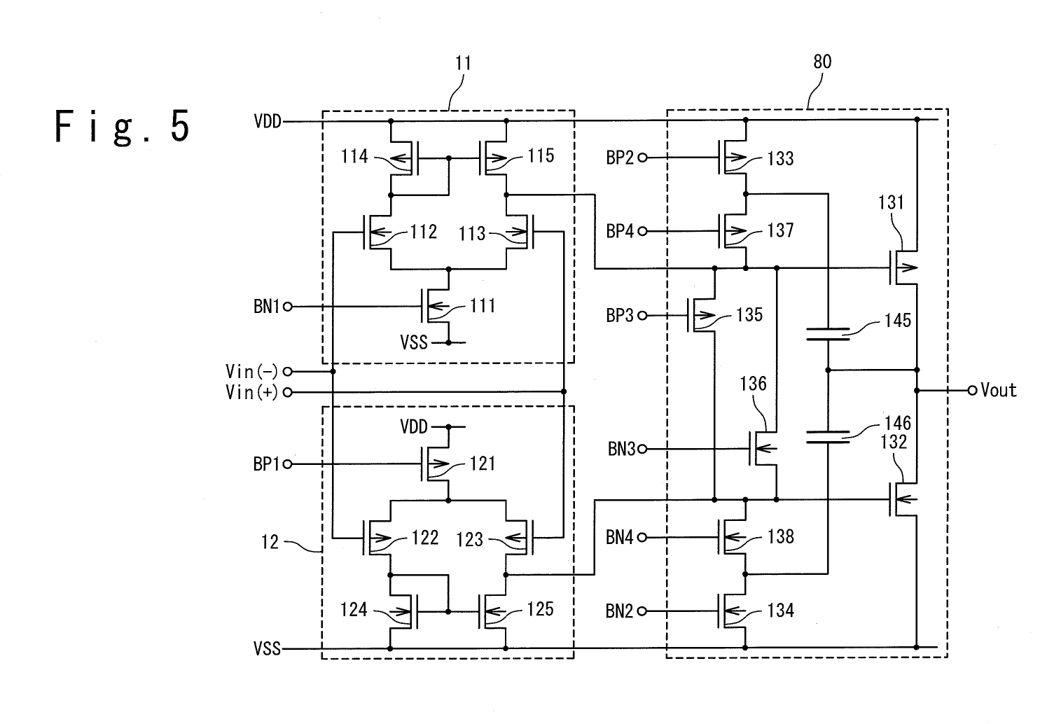

As shown in FIG. 5, the differential class AB amplifier circuit 1 includes an N receiving differential amplifier 11, a P receiving differential amplifier 12 and a class AB output circuit 80. The N receiving differential amplifier 11 includes N-channel MOS transistors 111 to 113 and P-channel MOS transistors 114, 115. The P receiving differential amplifier 12 includes P-channel MOS transistors 121 to 123 and N-channel MOS transistors 124, 125. The class AB output circuit 80 includes N-channel MOS transistors 132, 134, 136, 138, P-channel MOS transistors 131, 133, 135, 137 and phase compensating capacitances 145, 146 forming a phase compensating capacitance section.

In the N receiving differential amplifier 11, differential input signals Vin (+), Vin (−) are respectively applied to gates of the N-channel MOS transistors 112, 113 which form an N-channel differential pair. The P-channel MOS transistors 114, 115 form a current mirror circuit, are connected to the power voltage source VDD at their sources, are connected to drains of the N-channel MOS transistors 112, 113 at their drains, and are commonly connected to a connection node (a drain of the transistor 114) at their gates. The P-channel MOS transistors 114, 115 become active loads for the transistors 112, 113, respectively. The N-channel MOS transistor 111 receives a bias voltage BN1 at its gate and acts as a constant current source. An output of the N receiving differential amplifier 11 is outputted from a connection node between a drain of the N-channel MOS transistor 113 and a drain of the P-channel MOS transistor 115.

In the P receiving differential amplifier 12, the differential input signals Vin (+), Vin (−) are applied to gates of the P-channel MOS transistor 122, 123 which form a P-channel differential pair. The N-channel MOS transistors 124, 125 form s current mirror circuit, are connected to the power voltage source VSS at their sources, are connected to drains of the P-channel MOS transistors 122, 123 at their drains and are commonly connected to a connection node of the transistors 122, 124 (a drain of the transistor 124) at their gates. The N-channel MOS transistors 124, 125 become active loads for the transistors 122, 123, respectively. The P-channel MOS transistor 121 receives a bias voltage BP1 at its gate and acts as a constant current source. An output of the P receiving differential amplifier 12 is outputted from a connection node between a drain of the P-channel MOS transistor 123 and a drain of the N-channel MOS transistor 125.

In the class AB output circuit 80, the P-channel MOS transistor 131 and the N-channel MOS transistor 132 are serially connected between the power voltage sources VDD and VSS, and an output signal of the differential class AB amplifier 1 is outputted from the connection node Vout. The P-channel MOS transistor 135 which receives a bias voltage BP3 at its gate, and the N-channel MOS transistor 136 which receives a bias voltage BN3 at its gate, are parallely connected to each other. Meanwhile, one connection node of the transistors 135, 136 is connected to a gate of the P-channel MOS transistor 131 in the output stage to which the output of the N receiving differential amplifier 11 is connected. The P-channel MOS transistor 137 which receives a bias voltage BP4 at its gate and the P-channel MOS transistor 133 which receives bias voltage BP2 at its gate are serially connected between the one connection node and the power voltage source VDD. The other connection node is connected to a gate of the N-channel MOS transistor 132 in the output stage to which the output of the P receiving differential amplifier 12 is connected. Furthermore, the N-channel MOS transistor 138 which receives a bias voltage BN4 at is gate and the N-channel MOS transistor 134 which receives a bias voltage BN2 at its gate are serially connected between the other connection node and the power voltage source VSS.

The phase compensating capacitance 145 is connected between a connection node of the P-channel MOS transistors 133, 137 and the output node Vout. The phase compensating capacitance 146 is connected between a connection node of the N-channel MOS transistors 138, 134 and the output node Vout.

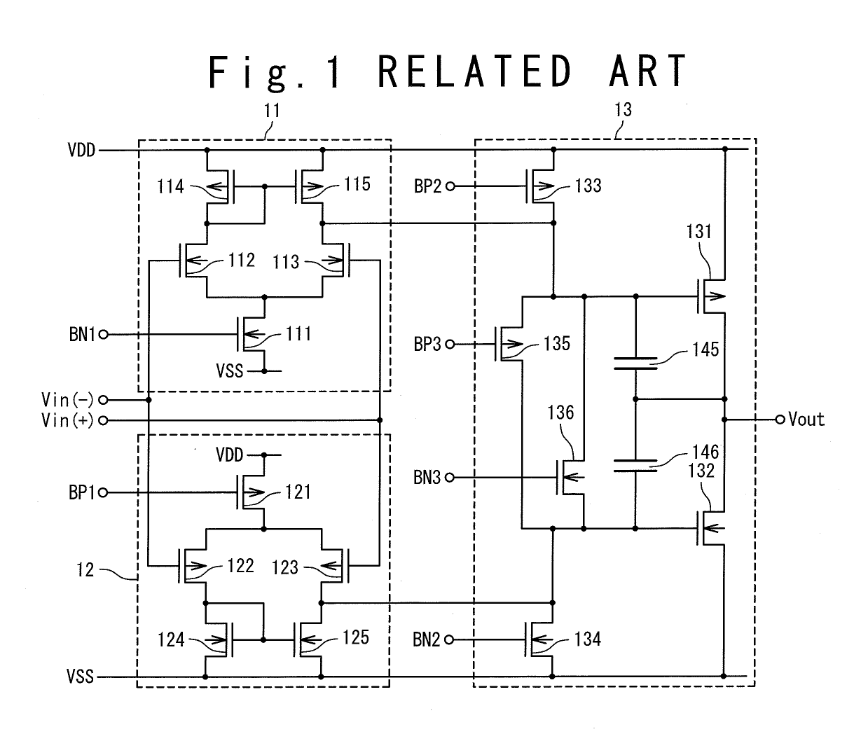

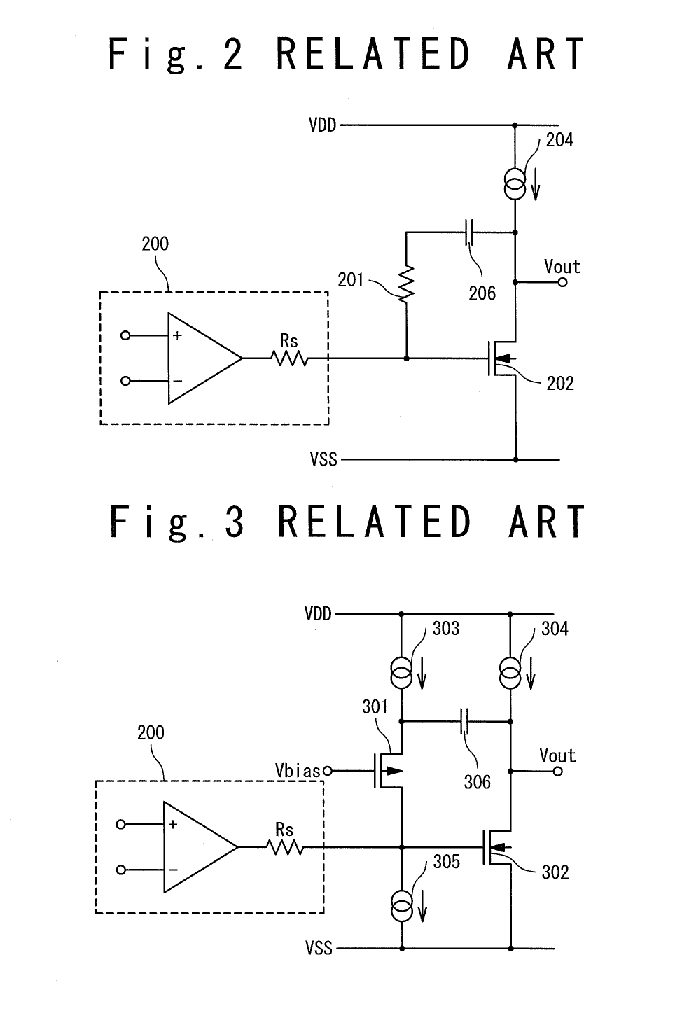

When comparing the differential class AB amplifier shown in FIG. 5 with the differential class AB amplifier shown in FIG. 1, the P-channel MOS transistor 137 and the N-channel MOS transistor 138 are added to the differential class AB amplifier shown in FIG. 1. In the differential class AB amplifier shown in FIG. 5, the node of the phase compensating capacitance 145 connected to the gate of the P-channel MOS transistor 131 in FIG. 1 is connected to the gate of the P-channel MOS transistor 131 via the P-channel MOS transistor 137. Similarly, the node of the phase compensating capacitance 146 connected to the gate of the N-channel MOS transistor 132 in FIG. 1 is connected to the gate of the N-channel MOS transistor 132 via the N-channel MOS transistor 138 in FIG. 5.

By the connection as shown in FIG. 5, the P-channel MOS transistor 137 acts as a current buffer transistor for cutting a current feed forward path to the phase compensating capacitance 145. The N-channel MOS transistor 138 acts as a current buffer transistor for cutting the current feed forward path to the phase compensating capacitance 146. Consequently, the P-channel MOS transistor 137 and the N-channel MOS transistor 138 which act as the current buffer transistors can block the frequency-dependent current feed forward paths, thereby preventing deterioration of the phase margin.

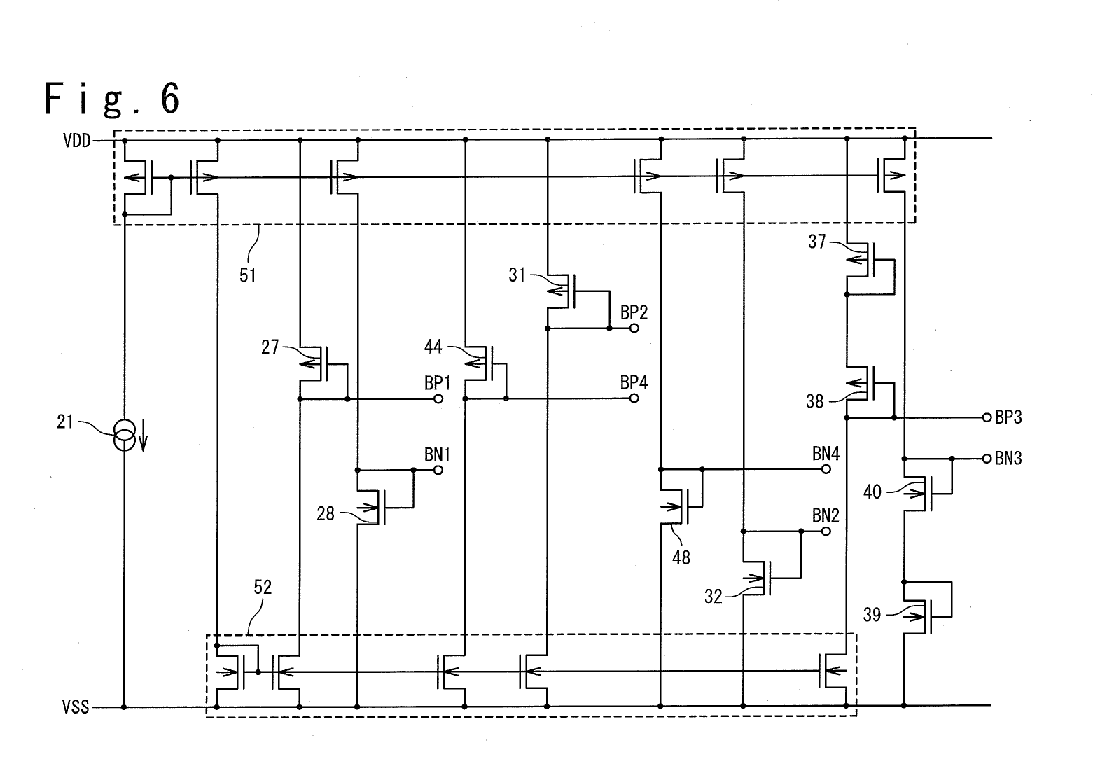

The common bias circuit 2 for supplying the bias voltage to the plurality of output circuits 1 as shown in FIG. 5 includes, as shown in FIG. 6, a constant current source 21, a P-channel current mirror circuit 51, an N-channel current mirror circuit 52, P-channel MOS transistors 27, 31, 37, 38, 44 and N-channel MOS transistors 28, 32, 39, 40, 48. The constant current source 21 is connected to an input node of the P-channel current mirror circuit 51. One output node of the P-channel current mirror circuit 51 is connected to an input node of the N-channel current mirror circuit 52. Thus, a current set by the constant current source 21 symmetrically flows to the output nodes of the P-channel current mirror circuit 51 and the N-channel current mirror circuit 52.

The P-channel MOS transistors 27, 44, 31 connected between the output node of the N-channel current mirror circuit 52 and the power voltage source VDD are each diode-connected and supply the bias voltages BP1, BP4, BP2, respectively, which are each lower than the voltage provided by the power voltage source VDD by a threshold voltage for one transistor. Similarly, the P-channel MOS transistors 37, 38 are each diode-connected and supply the bias voltage BP3 which is lower than the voltage provided by the power voltage source VDD by a threshold voltage for two transistors.

The N-channel MOS transistors 28, 48, 32 connected between the output node of the P-channel current mirror circuit 51 and the power voltage source VSS are each diode-connected and supply the bias voltages BN1, BN4, BN2, respectively, which are each higher than the voltage provided by the power voltage source VSS by a threshold voltage for one transistor. Similarly, the N-channel MOS transistors 39, 40 are each diode-connected and supply the bias voltage BN3 which is higher than the voltage provided by the power voltage source VSS by a threshold voltage for two transistors.

Since the common bias circuit 2 commonly supplies the bias voltage to the plurality of output circuits 1 in this manner, in the output circuit 1, it is only necessary to add the transistor which receives the bias voltage and acts as the current buffer. Also in the common bias circuit 2, only the transistors 44, 48 for supplying the bias voltages BP4, BN4, respectively, are added, which does not represent a substantial increase. Therefore, it is possible to provide the differential class AB amplifier circuit capable of improving the phase margin without adding many transistors.

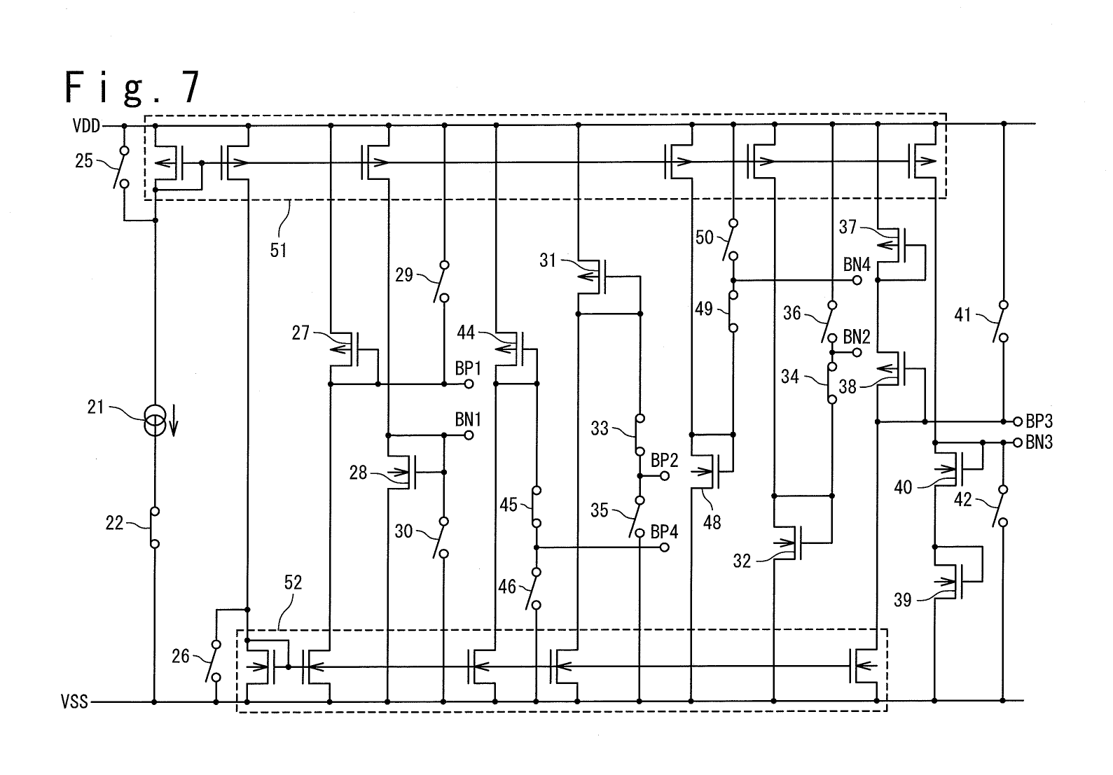

To measure a leak current of such differential class AB amplifier circuit 1, the bias voltage to be supplied to each transistor in the differential class AB amplifier circuit 1, which acts as the constant current source, may be blocked in a test mode operation. That is, in a case of the P-channel MOS transistor, the bias voltage is made equal to the voltage provided by the power voltage source VDD and in a case of the N-channel MOS transistor, the bias voltage is made equal to the voltage provided by the power voltage source VSS. FIG. 7 shows a configuration of the common bias circuit 2 which addresses the test mode operation.

The common bias circuit 2 shown in FIG. 7 is obtained by providing switch sections including switches 22, 25, 26, 29, 30, 45, 46, 33, 35, 49, 50, 34, 36, 41, 42 in the common bias circuit 2 shown in FIG. 6. The switch 22 forming a switch section is serially inserted to the constant current source 21 to control current supply from the constant current source 21. In the test mode operation, current supply is stopped. The switch 25 forming a switch section is inserted between the input node of the P-channel current mirror circuit 51 and the power voltage source VDD in parallel with the P-channel current mirror circuit 51 to control an operation of the P-channel current mirror circuit 51. The switch 26 forming a switch section is inserted between the input node of the N-channel current mirror circuit 52 and the power voltage source VSS in parallel with the N-channel current mirror circuit 52 to control an operation of the N-channel current mirror circuit 52. In the test mode operation, the current mirror circuits 51, 52 stop their operations.

The switch 29 forming a switch section is inserted so as to short-circuit a gate of the P-channel MOS transistor 27 to the power voltage source VDD. When the switch 29 is closed, a voltage provided by the power voltage source VDD is supplied as the bias voltage BP1. The switch 30 forming a switch section is inserted so as to short-circuit a gate of the N-channel MOS transistor 28 to the power voltage source VSS. When the switch 30 is closed, a voltage provided by the power voltage source VSS is supplied as the bias voltage BN1. In the test mode operation, the transistors 111, 121 are put into OFF states and the differential amplifiers 11, 12 stop their amplifying functions.

The switch 45 and the switch 46 forming a switch section switch between whether to output a voltage generated by the P-channel MOS transistor 44 or to output the voltage provided by the power voltage source VSS as the bias voltage BP4. The switch 33 and the switch 35 forming a switch section switch between whether to output a voltage generated by the P-channel MOS transistor 31 or to output the voltage provided by the power voltage source VDD as the bias voltage BP2. In the test mode operation, the P-channel MOS transistors 133, 137 are put into an ON state, the voltage provided by the power voltage source VDD is applied to a gate of the P-channel MOS transistor 131 as an output transistor and the P-channel MOS transistor 131 is put into the OFF state.

The switch 49 and the switch 50 forming a switch section switch between whether to output a voltage generated by the N-channel MOS transistor 48 or to output the voltage provided by the power voltage source VDD as the bias voltage BN4. The switch 34 and the switch 36 forming a switch section switch between whether to output a voltage generated by the N-channel MOS transistor 32 or the voltage provided by the power voltage source VDD as the bias voltage BN2. In the test mode operation, the N-channel MOS transistors 134, 138 are put into the ON state, the voltage provided by the power voltage source VSS is applied to a gate of the N-channel MOS transistor 132 as an output transistor and the N-channel MOS transistor 132 is put into the OFF state.

The switch 41 forming a switch section is inserted so as to short-circuit a gate (drain) of the P-channel MOS transistor 38 to the power voltage source VDD. When the switch 41 is closed, the voltage provided by the power voltage source VDD is supplied as the bias voltage BP3. The switch 42 forming a switch section is inserted so as to short-circuit a gate (drain) of the N-channel MOS transistor 40 to the power voltage source VSS. When the switch 41 is closed, the voltage provided by the power voltage source VSS is supplied as the bias voltage BN3. In the test mode operation, the P-channel MOS transistor 135 and the N-channel MOS transistor 136 are put into the OFF state.

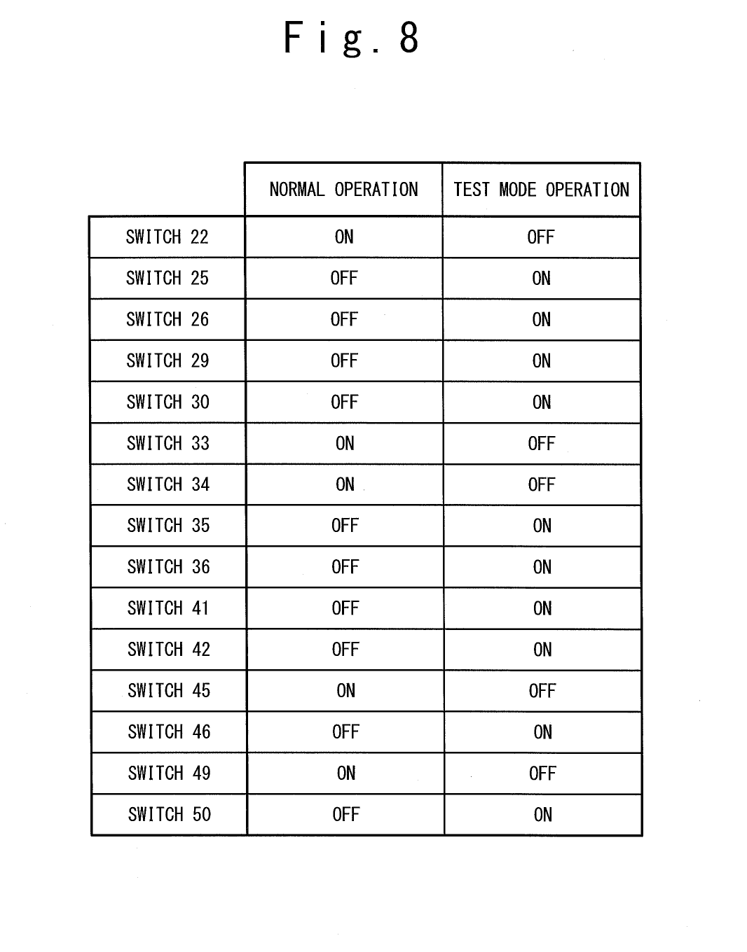

Consequently, as shown in FIG. 8, in a normal operation, the switches 22, 33, 34, 45, 49 are closed and the switches 25, 26, 29, 30, 35, 36, 41, 42, 46, 50 are opened. At this time, the connection of common bias circuit 2 as shown in FIG. 6 is achieved and a predetermined bias voltage is supplied to each transistor in the differential class AB amplifier 1. In the test mode operation, the switches 22, 33, 34, 45, 49 are opened and the switches 25, 26, 29, 30, 35, 36, 41, 42, 46, 50 are closed. At this time, the bias voltage is supplied to each transistor in the differential class AB amplifier 1 so that each transistor is reliably put into the ON or OFF state and the amplifying function is stopped. Therefore, a leak current of the differential class AB amplifier circuit 1 can be measured.

As described above, the class AB output circuit 80 includes the P-channel MOS transistor 133 and the N-channel MOS transistor 134 as two constant current sources and the transistors 137, 138 act as current buffers.

As shown in FIG. 3, the phase compensating circuit provided with the current buffer transistor for a zero point compensating effect requires the constant current source 303 for the source of the current buffer transistor and the current source 305 for the drain of the current buffer transistor, and the bias voltage supplied from the bias circuit is required for the gate of the current buffer transistor. By these two constant current sources and the bias voltage, the current buffer transistor 301 acts as a current buffer in terms of phase compensating capacitance and performs phase compensation with the zero point compensating effect.

The class AB output circuit 80 shown in FIG. 5 includes the P-channel MOS transistor 133 and the N-channel MOS transistor 134 as two constant current sources, and these two constant current sources are used as a source-side constant current source and a drain-side constant current source, respectively, of the phase compensating circuit having the zero point compensating effect. In other words, by means of the two constant current sources 133, 134 provided in the class AB output circuit 80, a constant current flows to the transistors 137, 138 and the bias voltages BP4, BN4 are supplied from the common bias circuit 2 and are applied to gates of the transistors 137, 138, respectively. Therefore, the transistors 137, 138 act as the current buffers when viewed from the phase compensating capacitances 145, 146 connected between sources of the transistors 137, 138 and the output Vout of the class AB output circuit 80.

As described above, in the class AB output circuit 80, a circuit for generating the necessary bias voltages is disposed in the common bias circuit 2 and the number of added transistors in the differential class AB amplifier circuit 1 is two. Since the circuit for generating the bias voltages is made common, as compared to a case where the bias circuits are separately provided, the area occupied by the circuit can be reduced. That is, stability of the differential class AB amplifier circuit 1 can be improved by using the phase compensating circuit having the zero point compensating effect while suppressing an increase in the area of the data line driver circuit 7.

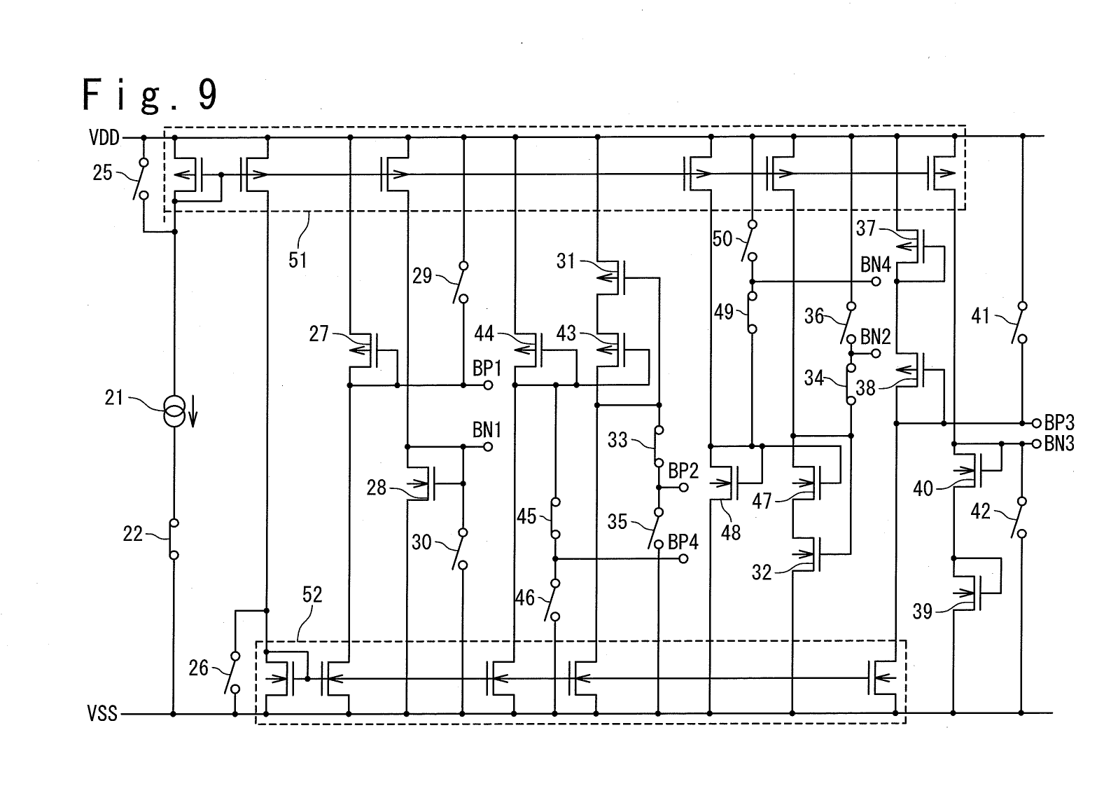

As shown in FIG. 9, a P-channel MOS transistor 43 and an N-channel MOS transistor 47 may be added to the common bias circuit 2. The P-channel MOS transistor 43 is connected between the drain and the gate of the diode-connected P-channel MOS transistor 31, and a gate voltage of the P-channel MOS transistor 44 is applied to a gate of the P-channel MOS transistor 43. The N-channel MOS transistor 47 is connected between the drain and the gate of the diode-connected N-channel MOS transistor 32, and a gate voltage of the N-channel MOS transistor 48 is applied to a gate of the N-channel MOS transistor 47.

With such a circuit configuration, P-channel MOS transistors 31, 43, 44 in the common bias circuit 2 shown in FIG. 9 and the P-channel MOS transistors 133, 137 in the differential class AB amplifier 1 shown in FIG. 5 form a low-voltage cascode current mirror circuit. The N-channel MOS transistors 32, 47, 48 in the common bias circuit 2 shown in FIG. 9 and the N-channel MOS transistors 134, 138 in the differential class AB amplifier circuit 1 shown in FIG. 5 form a low-voltage cascode current mirror circuit.

As a result, a drain-to-source voltage of the P-channel MOS transistor 31 becomes equal to a drain-to-source voltage of the P-channel MOS transistor 133 and a drain-to-source voltage of the N-channel MOS transistor 32 becomes equal to a drain-to-source voltage of the N-channel MOS transistor 134. Equalization of these drain-to-source voltages can prevent mismatch of mirror current values due to the Early effect, thereby realizing a high-accuracy current mirror circuit.

Also in the common bias circuit 2, values of currents flowing to the transistors 137, 138 are fixed by the constant current sources of the P-channel MOS transistor 133 and the N-channel MOS transistor 134, respectively. The common bias circuit 2 supplies the bias voltage BP4 to the gate of the P-channel MOS transistor 137 and the bias voltage BN4 to the gate of the N-channel MOS transistor 138, and the transistors 137, 138 act as the current buffers. Accordingly, phase compensation with the zero point compensating effect can be achieved.

As described above, in the class AB output circuit 80, the transistors 133, 134 are used as the constant current sources. When a mismatch between the current values of the constant current source transistors 133, 134 occurs, the differential currents flow to the differential amplifiers 11, 12 and appear as an output offset voltage. Thus, by increasing the accuracy of the current value of the current mirror circuit as described above, the output offset voltage can be prevented from occurring. The test mode operation can be achieved by controlling the switches as shown in FIG. 8 as in switch control in the common bias circuit 2 shown in FIG. 7.

As described above, by applying this technique to, for example, an LCD driver LSI for driving an LCD panel, even when driving a panel with a large load, a stable output can be easily obtained at high speed. Furthermore, high stability can be obtained with relatively lower costs while suppressing an increase in the area. In addition, even if the liquid crystal panel is further increased in size, reliability of products can be improved at low costs.

The embodiments of the present invention described above can be combined as necessary within a range that has no contradiction.

What is claimed is:

1. A driver circuit with a differential class AB amplifier circuit comprising:
a first differential amplifier circuit configured to amplify differential input signals and output a first signal in a first voltage range;
a second differential amplifier circuit configured to amplify said differential input signals and output a second signal in a second voltage range; and
a class AB output circuit configured to input said first and said second signals as differential signals and amplify said differential signals,
wherein said class AB output circuit comprises:
a phase compensating capacitance section; and
a current buffer circuit configured to control a current flowing through said phase compensating capacitance section.

2. The driver circuit according to claim 1 wherein said phase compensating capacitance section comprises a first and a second phase compensating capacitances and said class AB output circuit further comprises:
a first output transistor and a second output transistor which are serially connected between a first and a second power voltage sources;
an output node connected to a point where said first transistor is connected to said second output transistor;
a first current buffer transistor serially connected with said first phase compensating capacitance between said output node and a gate of said first output transistor wherein said gate is configured to receive said first signal;
a first constant current source transistor connected between a source of said first current buffer transistor and said first power voltage source;
a second current buffer transistor serially connected with said second phase compensating capacitance between said output node and a gate of said second output transistor wherein said gate is configured to receive said second signal; and
a second constant current source transistor connected between a source of said second current buffer transistor and said second power voltage source.

3. The driver circuit according to claim 2, further comprising:
a plurality of said differential class AB amplifier circuits; and
a bias circuit configured to provide bias voltage to each of said plurality of the differential class AB amplifier circuit,
wherein said bias circuit comprise:
a constant current source;
a current mirror circuit configured to provide a constant current based on said constant current source to a plurality of circuits;
a first bias transistor configured to be diode-connected and provide a first bias voltage based on the constant current provided by said current mirror circuit to said first current buffer transistor of said each differential class AB amplifier circuit;
a second bias transistor configured to be diode-connected and provide a second bias voltage based on the constant current provided by said current mirror circuit to said second current buffer transistor of said each differential class AB amplifier circuit;
a third bias transistor configured to be diode-connected and provide a third bias voltage based on the constant current provided by said current mirror circuit to said first current buffer transistor of said each differential class AB amplifier circuit; and
a fourth bias transistor configured to be diode-connected and provide a fourth bias voltage based on the constant current provided by said current mirror circuit to said second current buffer transistor of said each differential class AB amplifier circuit.

4. The driver circuit according to claim 3 wherein said bias circuit further comprises:
a first cascode transistor configured to be controlled by a gate voltage of said first bias transistor, be connected between a gate and a drain of said third bias transistor and form a cascode current mirror circuit; and
a second cascode transistor configured to be controlled by a gate voltage of said second bias transistor, be connected between a gate and a drain of said fourth bias transistor and form a cascode current mirror circuit.

5. The driver circuit according to claim 4 wherein said bias circuit further comprises:
a switch section configured to stop in a test mode operation a current supply of said constant current source;
a switch section configured to stop in said test mode operation said constant current provided to said current mirror circuit;
a switch section configured to switch a source of said first bias voltage provided to said first current buffer transistor to said second power voltage source;
a switch section configured to switch a source of said second bias voltage provided to said second current buffer transistor to said first power voltage source;
a switch section configured to switch a source of said third bias voltage provided to said first constant current source transistor to said second power voltage source; and
a switch section configured to switch a source of said fourth bias voltage provided to said second constant current source transistor to said first power voltage source.

6. The driver circuit according to claim 5 wherein said class AB output circuit further comprises a third and a fourth constant current source transistors which are parallelly connected between a drain of said first current buffer transistor and a drain of said second current buffer transistor.

7. The driver circuit according to claim 6 wherein said bias circuit further comprises:
a fifth bias transistor configured to provide a fifth bias voltage based on a constant current provided by said current mirror circuit, to said third constant current source transistor; and
a sixth bias transistor configured to provide a sixth bias voltage based on a constant current provided by said current mirror circuit, to said fourth constant current source transistor.

8. The driver circuit according to claim 7 wherein said bias circuit further comprises:
a switch section configured to switch a source of said fifth bias voltage provided to said third constant current source transistor to said first power voltage source; and
a switch section configured to switch a source of said sixth bias voltage provided to said fourth constant current source transistor to said second power voltage source.

9. A display device comprising:
a display panel; and
a differential class AB amplifier circuit configured to drive said display panel,
wherein said differential class AB amplifier circuit comprises:
a first differential amplifier circuit configured to amplify differential input signals and output a first signal in a first voltage range;
a second differential amplifier circuit configured to amplify said differential input signals and output a second signal in a second voltage range; and
a class AB output circuit configured to input said first and said second signals as differential signals and amplify said differential signals,
wherein said class AB output circuit comprises:
a phase compensating capacitance section; and
a current buffer circuit configured to control a current flowing through said phase compensating capacitance section.

10. The display device according to claim 9 wherein said phase compensating capacitance section comprises a first and a second phase compensating capacitances and said class AB output circuit further comprises:
a first output transistor and a second output transistor which are serially connected between a first and a second power voltage sources;
an output node connected to a point where said first transistor is connected to said second output transistor;
a first current buffer transistor serially connected with said first phase compensating capacitance between said output node and a gate of said first output transistor wherein said gate is configured to receive said first signal;
a first constant current source transistor connected between a source of said first current buffer transistor and said first power voltage source;
a second current buffer transistor serially connected with said second phase compensating capacitance between said output node and a gate of said second output transistor wherein said gate is configured to receive said second signal; and
a second constant current source transistor connected between a source of said second current buffer transistor and said second power voltage source.

11. The display device according to claim 10 further comprising:
a plurality of the differential class AB amplifier circuits; and
a bias circuit configured to provide bias voltage to each of said plurality of the differential class AB amplifier circuit,
wherein said bias circuit comprise:
a constant current source;
a current mirror circuit configured to provide a constant current based on said constant current source to a plurality of circuits;
a first bias transistor configured to be diode-connected and provide a first bias voltage based on the constant current provided by said current mirror circuit to said first current buffer transistor of said each differential class AB amplifier circuit;
a second bias transistor configured to be diode-connected and provide a second bias voltage based on the constant current provided by said current mirror circuit to said second current buffer transistor of said each differential class AB amplifier circuit;
a third bias transistor configured to be diode-connected and provide a third bias voltage based on the constant current provided by said current mirror circuit to said first current buffer transistor of said each differential class AB amplifier circuit; and
a fourth bias transistor configured to be diode-connected and provide a fourth bias voltage based on the constant current provided by said current mirror circuit to said second current buffer transistor of said each differential class AB amplifier circuit.

12. The display device according to claim 11 wherein said bias circuit further comprises:
a first cascode transistor configured to be controlled by a gate voltage of said first bias transistor, be connected between a gate and a drain of said third bias transistor and form a cascode current mirror circuit; and
a second cascode transistor configured to be controlled by a gate voltage of said second bias transistor, be connected between a gate and a drain of said fourth bias transistor and form a cascode current mirror circuit.

13. The display device according to claim 12 wherein said bias circuit further comprises:
a switch section configured to stop in a test mode operation a current supply of said constant current source;
a switch section configured to stop in said test mode operation said constant current provided to said current mirror circuit;
a switch section configured to switch a source of said first bias voltage provided to said first current buffer transistor to said second power voltage source;
a switch section configured to switch a source of said second bias voltage provided to said second current buffer transistor to said first power voltage source;
a switch section configured to switch a source of said third bias voltage provided to said first constant current source transistor to said second power voltage source; and
a switch section configured to switch a source of said fourth bias voltage provided to said second constant current source transistor to said first power voltage source.

14. The display device according to claim 13 wherein said class AB output circuit further comprises a third and a fourth constant current source transistors which are parallelly connected between a drain of said first current buffer transistor and a drain of said second current buffer transistor.

15. The display device according to claim 14 wherein said bias circuit further comprises:
a fifth bias transistor configured to provide a fifth bias voltage based on a constant current provided by said current mirror circuit, to said third constant current source transistor; and
a sixth bias transistor configured to provide a sixth bias voltage based on a constant current provided by said current mirror circuit, to said fourth constant current source transistor.

16. The display device according to claim 15 wherein said bias circuit further comprises:
a switch section configured to switch a source of said fifth bias voltage provided to said third constant current source transistor to said first power voltage source; and
a switch section configured to switch a source of said sixth bias voltage provided to said fourth constant current source transistor to said second power voltage source.

17. A method of driving a circuit comprising:
amplifying differential input signals to generate a first signal in a first voltage range;
amplifying said differential input signals to generate a second signal in a second voltage range;
amplifying said first and said second signals as differential signals to generate an output signal;
compensating phase delay in said output signal with a phase compensating capacitance; and
controlling a current flowing through said phase compensating capacitance to control said compensating.
